(19) United States
(12) Patent Application Publication
(10) Pub. No.: US 2018/0371612 A1
(43) Pub. Date: Dec. 27, 2018

(54) Low Temperature Process for Forming Silicon-Containing Thin Layer

(71) Applicants: Wonik Materials Co., Ltd., Chungcheongbuk-do (KR); Nova-Kem, LLC, Germantown, WI (US)

(72) Inventors: Seung Ho Yoo, Sejong-si (KR); Suhyong Yun, Sejong-si (KR); Sun Kyung Park, Chungcheongbuk-do (KR); Heonjong Jeong, Seoul (KR); Hima Kumar Lingam, Germantown, WI (US); Yunjung Choi, Seoul (KR); Daewoong Suh, Seoul (KR)

(21) Appl. No.: 15/634,241

(22) Filed: Jun. 27, 2017

(51) Int. Cl. C23C 16/455; C23C 16/40; H01L 21/02

(52) U.S. Cl. CPC C23C 16/45553; C23C 16/401; H01L 21/0228; H01L 21/02164; H01L 21/02211

(57) ABSTRACT

The present invention relates to a method for forming a silicon-containing thin layer at a low temperature, and in particular, to a method for forming a silicon-containing thin layer by carrying out atomic layer deposition (ALD) at a low temperature.

### CROSS-REFERENCE(S) TO RELATED APPLICATIONS

### Background of the Invention

### Field of the Invention

The present invention relates to a method for forming a silicon-containing thin layer by carrying out atomic layer deposition (ALD) at a low temperature.

### Description of the Related Art

Silicon oxide layers are generally one of most commonly used thin layers in a semiconductor due to its excellent interface with silicon and excellent dielectric properties. In preparing a silicon-based semiconductor device, a silicon oxide layer is usable in a gate insulating layer, a diffusion mask, a sidewall spacer, a hard mask, anti-reflective coating, passivation and capsulation, and other various applications. The silicon oxide layer has also been increasingly more important for passivation of other compound semiconductor devices.

As existing common methods for depositing a silicon oxide layer, the following two methods have been widely used: (1) an oxidation process oxidizing silicon at a temperature of higher than 1000° C.; and (2) a chemical vapor deposition (CVD) process providing two or more sources at a temperature of 600° C. to 800° C. However, these methods induce diffusion at an interface, particularly, diffusion of dopants in a wafer, due to a high deposition temperature, and decline electrical properties of the device.

In view of such problems, U.S. Pat. No. 6,090,442 discloses a method for forming a silicon oxide layer at a temperature of lower than 200° C. using a catalyst and a small amount of source of supply. The method disclosed in U.S. Pat. No. 6,090,442 uses a catalyst capable of depositing a silicon oxide even at a temperature of 200° C. or lower.

However, when depositing a silicon oxide layer at a temperature of room temperature to 50° C., a temperature inside a reactor is low and reaction byproducts and unreacted reaction solutions such as HCDS and H₂O are not readily removed, and such byproducts are present in the thin layer as particles after deposition causing a problem of declining thin layer properties. When depositing a silicon oxide layer at a temperature of 50° C. or higher, byproducts such as reacted and unreacted HCDS and H₂O are readily removed, however, a deposition rate of the thin layer at the time is very low resultantly decreasing a device yield.

In addition, a method of depositing a silicon oxide layer using an existing PEALD method deposits a thin layer at a high temperature of approximately 300° C., and therefore, causes a problem of losing an organic photoresist at the high temperature in most cases, and forming a uniform thin layer is limited. Meanwhile, a PEALD process at a low temperature has a problem in that a thin layer having a sufficient thickness is not formed.

In addition, as a method for using a plasma process at a low temperature, a method of depositing a silicon oxide layer at a low temperature using plasma enhanced chemical vapor deposition (PECVD) has been used, however, a silicon dioxide layer deposited from silane through PECVD at approximately 200° C. or lower has a disadvantage of exhibiting poor quality.

The following Reference Documents 1 to 3 relate to an atomic layer deposition technology, and Reference Document 1 relates to a technology of depositing silicon oxide through atomic layer deposition at 250° C. or higher using a bisdiethylaminosilane (BDEAS) precursor that is an aminosilane-based precursor, and an O₃ oxidizer. Reference Document 2 relates to a technology of ALD using a NH₃ catalyst with a SiCl₄ precursor and a H₂O oxidizer at room temperature, and Reference Document 3 describes a technology of depositing silicon oxide at a low temperature of 50° C. to 140° C. using a pyridine catalyst with a hexachlorodisilane (HCDS) precursor and a H₂O oxidizer. However, as described above, Reference Document 1 requires a high temperature of 250° C. or higher, and Reference Documents 2 and 3 still have limits in that, although deposition occurs at low temperatures, a catalyst is always required.
Reference Document 1. “Impact of aminosilane precursor structure on silicon oxides by ALD”, Mark L. O'neill et al., The electrochemical society Interface, 2011, pp. 33˜37
Reference Document 2. “Atomic layer deposition of SiO₂ at room temperature using NH3 catalyzed sequential surface reactions”, Surface science, 447, 2000, pp. 81˜90
Reference Document 3. U.S. Pat. No. 7,077,904

In view of the above, the present invention is directed to providing a method for preparing a silicon oxide layer capable of obtaining a thin layer having a target thickness in uniform and excellent quality using a process capable of depositing at a low temperature without supplying a separate catalyst, and in addition thereto, having a high deposition rate without requiring a catalyst and additional equipment for obtaining a high temperature.

### SUMMARY OF THE INVENTION

The present invention has been made in view of the above, and an object of the present invention is to provide a method for forming a silicon-containing thin layer through an atomic layer deposition (ALD) process at a low temperature.

However, objects of the present invention are not limited to the objects described above, and other objects that are not mentioned will be clearly understood to those skilled in the art from the descriptions provided below.

One embodiment of the present invention provides a method for forming a silicon-containing thin layer through atomic layer deposition (ALD) at a temperature of 250° C. or lower, wherein an aminosilane precursor represented by the following Chemical Formula 1 or Chemical Formula 2 is used.

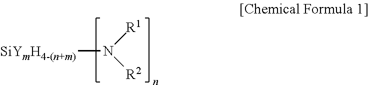

In Chemical Formula 1,

R¹ and R² may be each independently hydrogen or an alkyl group having 1 to 10 carbon atoms, or may form an N-containing heterocycloalkyl ring in a form linked to each other, and at least one or more of R¹ and R² are an alkyl group having 1 to 10 carbon atoms, Y is halogen, n is an integer of 1 to 4, m is an integer of 0 to 4, and 0<n+m<4. However, when m is an integer of 0, n is an integer of 1 to 3, both R¹ and R² may not be methyl, ethyl, isopropyl or butyl at the same time.

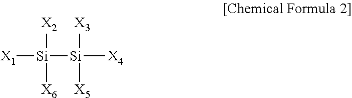

In Chemical Formula 2,

X₁ to X₆ are each independently hydrogen, halogen, an amino group unsubstituted or substituted with one or more alkyl groups having 1 to 10 carbon atoms, an alkyl group having 1 to 10 carbon atoms or —SiH₃₋ₙAₙ (herein, n is from 1 to 3, A is

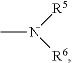

and R⁵ and R⁶ are each independently hydrogen or an alkyl group having 1 to 10 carbon atoms), and at least one or more of X₁ to X₆ are an amino group unsubstituted or substituted with an alkyl group having 1 to 10 carbon atoms.

Another embodiment of the present invention provides a silicon-containing thin layer prepared using the method for forming a silicon-containing thin layer.

### BRIEF DESCRIPTION OF THE DRAWINGS

The above and other objects, features and other advantages of the present invention will be more clearly understood from the following detailed description taken in conjunction with the accompanying drawings, in which:

FIG. 1 and FIG. 2 are graphs showing a silicon-containing thin layer growth per cycle depending on a precursor of Chemical Formula 5 and an ozone injection time with a substrate temperature of 150° C., a precursor temperature of 60° C., a line temperature of 80° C. and an ozone concentration of 180 g/cm³ according to one example of the present invention;

FIG. 3a is a graph showing a test result of cycle deposition in the same manner while varying the substrate temperature to 50° C. to 250° C. with a precursor injection time of 3 seconds and an ozone injection time of 20 seconds under the process condition of FIG. 1 and FIG. 2 according to one example of the present invention;

FIG. 3b is a graph showing a thin layer growth per cycle in processes according to Example 1 and Comparative Examples 1 to 3;

FIG. 4, FIG. 5 and FIG. 6 are graphs respectively showing capacitance density, capacitance equivalent thickness (CET) and leakage current density, which are electrical properties for a silicon-containing thin layer formed according to one example of the present invention;

FIG. 7 to FIG. 10 are graphs showing results of measuring auger electron spectroscopy (AES) for identifying impurities for a silicon-containing thin layer deposited at each deposition temperature (50° C., 80° C., 150° C. and 250° C.) according to one example of the present invention;

FIG. 11 shows graphs of a SiO₂ thin layer growth per cycle depending on a precursor of Chemical Formula 5 and an O₂ plasma injection time by producing O₂ plasma under a condition of a substrate temperature of 150° C., a precursor temperature of 60° C., a line temperature of 100° C., and 200 W;

FIG. 12 shows graphs of a SiO₂ thin layer growth per cycle depending on a precursor of Chemical Formula 5 and an O₂ plasma injection time by producing O₂ plasma under a condition of a substrate temperature of 50° C., a precursor temperature of 60° C., a line temperature of 100° C., and 200 W;

FIG. 13 shows a growth per cycle (GPC) of a silicon-containing thin layer prepared according to Example 2; and

FIG. 14 is a graph showing a result of measuring X-ray reflectivity (XRR) for identifying density for a SiO₂ thin layer deposited at each temperature according to one example of the present invention.

### DESCRIPTION OF SPECIFIC EMBODIMENTS

Hereinafter, preferred embodiments of the present invention will be described in more detail. However, the embodiments of the present invention may be modified to various other forms, and the scope of the present invention is not limited to the embodiments described below. In addition, the embodiments of the present invention are provided in order to more completely describe the present invention to those having average knowledge in the art.

One embodiment of the present invention provides a method for forming a silicon-containing thin layer through an atomic layer deposition (ALD) process at a temperature of 250° C. or lower.

In one embodiment of the present invention, the method forms a silicon-containing thin layer through an atomic layer deposition (ALD) process at a temperature of 250° C. or lower using aminosilane represented by the following Chemical Formula 1 or Chemical Formula 2 as a precursor.

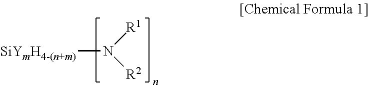

In Chemical Formula 1, R¹ and R² may be each independently hydrogen or an alkyl group having 1 to 10 carbon atoms, or may be linked to each other to have a form of a heterocycloalkyl ring including N, and at least one or more of R¹ and R² are an alkyl group having 1 to 10 carbon atoms, Y is halogen, n is an integer of 1 to 4, m is an integer of 0 to 4, and 0<n+m<4. However, when m is an integer of 0, n is an integer of 1 to 3, both R¹ and R² may not be methyl, ethyl, isopropyl or butyl at the same time.

In Chemical Formula 1, R¹ and R² are each independently hydrogen or an alkyl group having 1 to 10 carbon atoms, and herein, the alkyl group having 1 to 10 carbon atoms includes a linear or branched alkyl group having 1 to 10 carbon atoms. As one example, R¹ and R² may be may be the same or different and each independently methyl, ethyl, propyl, isopropyl, t-butyl, sec-butyl and the like. In addition, R¹ and R² may be linked to each other to have a form of an N-containing heterocycloalkyl ring having 2 to 20 carbon atoms.

In Chemical Formula 1, hydrogen linked to silicon may be substituted with halogen, and in this case, Y may be halogen selected from among F, Br, Cl and the like, and is preferably Cl and m is an integer of 0 to 4. When m is 0, Chemical Formula 1 may be represented by the following Chemical Formula 7.

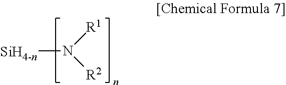

In Chemical Formula 7, R¹ and R² are each independently hydrogen or an alkyl group having 1 to 10 carbon atoms, may be linked to each other to form a cycloalkyl ring, and at least one or more of R¹ and R² are an alkyl group having 1 to 10 carbon atoms such as methyl, ethyl, propyl, isopropyl, t-butyl and sec-butyl, and n is an integer of 1 to 4. However, when n is an integer of 1 to 3, both R¹ and R² may not be methyl, ethyl, isopropyl or butyl at the same time. As one example, Chemical Formula 7 may be bis(methylethylamino)silane, bis(methylpropylamino)silane, bis(ethylpropylamino)silane, bis(diisopropylamino)silane and the like.

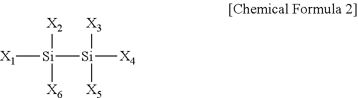

In Chemical Formula 2,

X₁ to X₆ are each independently hydrogen, halogen, an amino group unsubstituted or substituted with one or more alkyl groups having 1 to 10 carbon atoms, an alkyl group having 1 to 10 carbon atoms or —SiH₃₋ₙAₙ (herein, n is from 1 to 3, A is

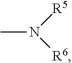

and R⁵ and R⁶ are each independently hydrogen or an alkyl group having 1 to 10 carbon atoms), and at least one or more of X₁ to X₆ are an amino group unsubstituted or substituted with an alkyl group having 1 to 10 carbon atoms.

In one embodiment of the present invention, at least one or more of X₁ to X₆ of Chemical Formula 2 are an amino group unsubstituted or substituted with an alkyl group having 1 to 10 carbon atoms, and more specifically, may be

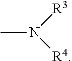

Herein, R³ and R⁴ may be each independently hydrogen or an alkyl group having 1 to 10 carbon atoms, or an N-containing heterocycloalkyl ring having a form linked to each other, and at least one thereof is an alkyl group having 1 to 10 carbon atoms. The alkyl group having 1 to 10 carbon atoms may be a linear or branched alkyl group having 1 to 10 carbon atoms, and as preferred one example, includes methyl, ethyl, propyl, isopropyl, t-butyl, sec-butyl and the like. In addition, R³ and R⁴ may have a form of an N-containing heterocycloalkyl ring having 2 to 20 carbon atoms in a form linked to each other.

In one embodiment of the present invention, one or more of X₁ to X₆ of Chemical Formula 2 may be halogen selected from among F, Br, Cl and the like, and are preferably Cl.

In one embodiment of the present invention, X₁ to X₄ of Chemical Formula 2 are hydrogen, X₅ and X₆ are each independently

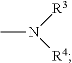

and R³ and R⁴ may be each independently an alkyl group having 1 to 10 carbon atoms such as methyl, ethyl, propyl, isopropyl, t-butyl and sec-butyl.

In one embodiment of the present invention, any one of X₁ to X₆ of Chemical Formula 2 may be —SiH₃₋ₙAₙ (herein, n is from 1 to 3, and A is

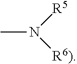

Among the aminosilane precursors, disilane and trisilane have a relatively weak Si—Si or Si—Si—Si bond and therefore, silicon is readily deposited at a low temperature. R⁵ and R⁶ may be each independently hydrogen or an alkyl group having 1 to 10 carbon atoms, and includes a linear or branched alkyl group having 1 to 10 carbon atoms. As one example, R⁵ and R⁶ may be methyl, ethyl, propyl, isopropyl, t-butyl, sec-butyl and the like.

In one embodiment of the present invention, the aminosilane may be any one of the following Chemical Formulae 3 to 6 as a precursor.

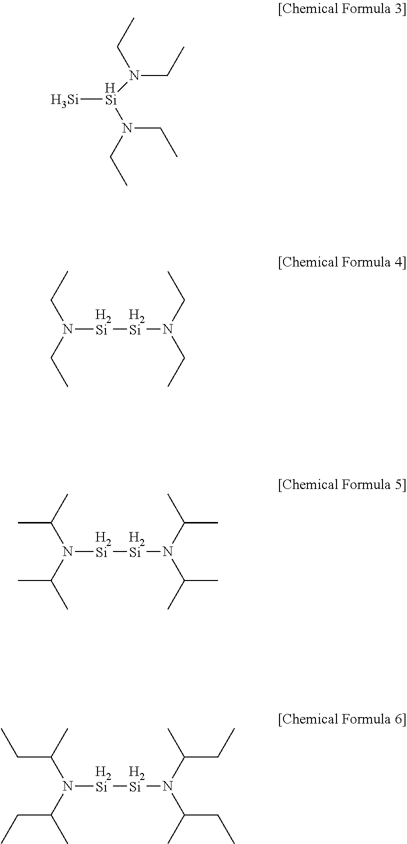

More preferably, as one embodiment of the present invention, the aminosilane precursor may be Chemical Formula 5. In addition, according to the present invention, a silicon-containing precursor may be further included in addition to the precursor represented by Chemical Formula 1 or Chemical Formula 2. Specific examples of such a precursor include phenylmethylaminosilane, trisilylamine, di-iso-propylaminosilane, di-secondary-butylaminosilane, phenylmethylaminosilane, hexamethyl disiloxane, dimethyl siloxane, methylsilane, dimethylsilane, diethylsilane, vinyl trimethylsilane, trimethylsilane, tetramethylsilane, ethylsilane, disilylmethane, 2,4-disilapentane, 1,4-disilabutane, 2,5-disilahexane, 2,2-disilylpropane, 1,3,5-trisilacyclohexane, dimethylphenylsilane and diphenylmethylsilane, dimethyldimethoxysilane, 1,3,5,7-tetramethylcyclotetrasoxane, 1,1,3,3-tetramethyldisiloxane, 1,3,5,7-tetrasila-4-oxo-heptane, 2,4,6,8-tetrasila-3,7-dioxo-nonane, 2,2-dimethyl-2,4,6,8-tetrasila-3,7-dioxo-nonane, octamethylcyclotetrasiloxane, pentamethylcyclopentasiloxane, 1,3,5,7-tetrasila-2,6-dioxo-cyclooctane, hexamethylcyclotrisiloxane, 1,3-dimethyldisiloxane, 3,5,7,9-pentamethylcyclopentasiloxane, hexamethoxydisiloxane and the like, but are not limited thereto.

The present invention relates to a method for forming a silicon-containing thin layer through atomic layer deposition (ALD) at a temperature of 250° C. or lower, and embodiments of the present invention include the atomic layer deposition (ALD) using all methods of plasma enhanced ALD, spatial ALD, atmospheric pressure ALD, selective ALD or the like.

In one embodiment of the present invention, the silicon-containing thin layer may be a thin layer including silicon oxide (SiOx), silicon nitride (SiNx), silicon oxynitride (SiON), silicon carbide (SiC), silicon carbonitride (SiCN) or combinations thereof.

In one embodiment of the present invention, oxygen source gases, nitrogen source gases, carbon source gases or combinations thereof may be used as a reaction gas reacting with the aminosilane precursor. More specifically, the reaction gas may include H₂O, O₂, O₃, N₂, NH₃, N₂H₄, NO, N₂O, NO₂, CO, CO₂ or combinations thereof, but is not limited thereto.

Hereinafter, embodiments of the present invention will be described in more detail.

In one embodiment of the present invention, the atomic layer deposition (ALD) includes a. increasing a temperature of a substrate to 20° C. to 250° C. by providing the substrate to an atomic layer deposition reactor; b. introducing one or more of the aminosilane precursors into the reactor; and c. introducing a reaction gas into the reactor.

More specifically, the atomic layer deposition (ALD) includes a. increasing a temperature of a substrate to 20° C. to 250° C. by providing the substrate to an atomic layer deposition reactor; b. introducing one or more of the aminosilane precursors into the reactor; c. purging the reactor with a purge gas; d. introducing a reaction gas into the reactor; and e. purging the atomic layer deposition reactor with a purge gas, and the step b to the step e may be repeated until a silicon-containing thin layer having a target thickness is deposited.

In one embodiment of the present invention, the silicon-containing thin layer may be a silicon oxide thin layer, and herein, an oxygen source gas, for example, O₃, may be used as the reaction gas.

In one embodiment of the present invention, plasma enhanced atomic layer deposition (PEALD) includes A. increasing a temperature of a substrate to 20° C. to 250° C. by providing the substrate to a plasma enhanced atomic layer deposition reactor; B. introducing one or more of the aminosilane precursors into the reactor; and C. introducing a reaction gas in a plasma state into the atomic layer deposition reactor. The reaction gas may be injected to the reactor in a plasma state from a plasma generator.

More specifically, the plasma enhanced atomic layer deposition (PEALD) includes A. increasing a temperature of a substrate to 20° C. to 250° C. by providing the substrate to a plasma enhanced atomic layer deposition reactor; B. introducing one or more of the aminosilane precursors into the reactor; C. introducing a reaction gas in a plasma state into the atomic layer deposition reactor; and D. purging the plasma enhanced atomic layer deposition reactor with a purge gas, and the step B to the step D may be repeated until a silicon-containing thin layer having a target thickness is deposited.

In one embodiment of the present invention, the silicon-containing thin layer may be a silicon oxide thin layer, and herein, an oxygen source gas, for example, O₂ in a plasma state, may be used as the reaction gas.

In another embodiment of the present invention, the substrate capable of being used is not particularly limited, and SiO₂, Si₃N₄, OSG, FSG, silicon carbide, hydrogenated silicon carbide, silicon nitride, hydrogenated silicon nitride, silicon carbonitride, hydrogenated silicon carbonitride, boronitride, photoresists, organic polymers, porous organic and inorganic materials, flexible substrates, metals such as copper and aluminum, III-V compound substrates, silicon/germanium (SiGe) substrates, epi-substrates, silicon-on-insulator (SOI) substrates, substrates of displays such as liquid crystal displays, LED displays and OLED displays, polymer-based flexible material substrates and the like may be included.

According to the present invention, silicon deposition may occur when heating a substrate to a low temperature of 250° C. or lower, and therefore, the substrate may be heated to a temperature of 20° C. to 250° C., preferably 20° C. to 200° C., and more preferably 50° C. to 150° C. In addition, when using the method according to the present invention, a silicon-containing thin layer is deposited at a high rate even at a temperature of 250° C. or lower, and the thin layer formed herein may have uniform layer properties as well as having excellent electrical properties.

The precursor compounds of Chemical Formula 3 to Chemical Formula 6 according to one example of the present invention have AG values of the following [Table 1]. This indicates that the following chemical formulae have AG values similar to [Chemical Formula 5] identified in specific one example of the present invention to be described below, and thereby have similar deposition properties when forming a silicon-containing thin layer.

TABLE 1

| | | Energy |
|---|---|---|
| Organic Aminosilane Precursor | Reaction | (kcal/mole) |
| SiH₃(iPr₂N) [DIPAS] | Silicon | ΔH −147.40/ |
| | Oxide (SiO₂) | ΔG −157.09 |
| SiH₃(sec-Bu₂N) [DSBAS] | Oxidation | ΔH −147.25/ |
| | Source (O₃) | ΔG −157.16 |
| 1,1-Si₂H₄(NEt₂)₂ | | ΔH −159.51/ |
| [Chemical Formula 3] | | ΔG −189.69 |
| 1,2-Si₂H₄(NEt₂)₂ | | ΔH −163.22/ |
| [Chemical Formula 4] | | ΔG −193.92 |
| Si₂H₄(iPr₂N)₂ [BDIPADS] | | ΔH −169.56/ |
| [Chemical Formula 5] | | ΔG −199.25 |
| Si₂H₄(sec-Bu₂N)₂ [BDSBADS] | | ΔH −173.36/ |
| [Chemical Formula 6] | | ΔG −204.63 |

Another embodiment of the present invention provides a silicon-containing thin layer prepared according to the method of the present invention. The prepared thin layer may have an O/Si ratio in a range of approximately 1.5 to approximately 2.0.

Hereinafter, a silicon-containing thin layer according to one example of the present invention is prepared. However, this is for illuminating the present invention only, and the scope of the present invention is not construed as being limited to the following examples.

### Example 1: Preparation of Silicon-Containing Thin Layer According to Atomic Layer Deposition (ALD) Process

A substrate was prepared by, as a Si wafer (LG Siltron inc) and p-type wafer having resistance of approximately 10 Ωcm, removing a native oxide layer after etching with a HF (10%) solution and washing with distilled water. On the Si wafer (3 cm×3 cm to 4 cm×4 cm), silicon oxide (SiO₂) was deposited according to the following process using a 4-inch traveling wave type ALD reactor (CN-1 Co.).

First, the substrate was heated to a temperature of 50° C. to 250° C., and to the heated substrate, an aminosilane precursor heated to 40° C. to 100° C. was injected for 3 seconds to 5 seconds. Herein, a compound of Chemical Formula 5 was used as the aminosilane precursor.

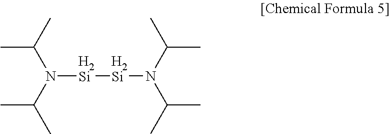

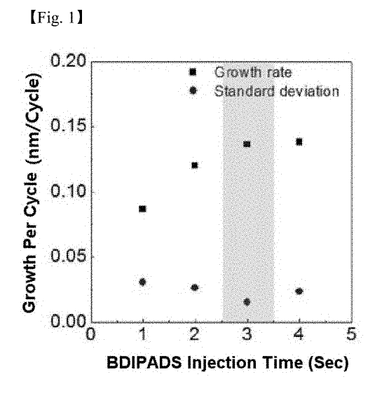

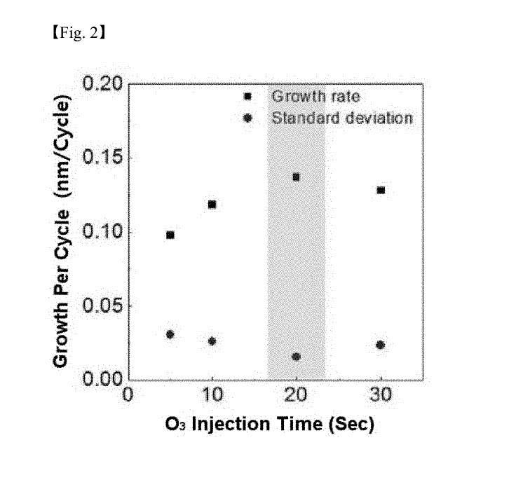

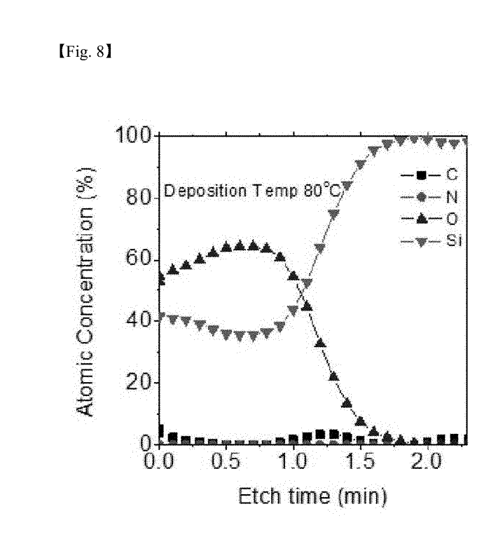

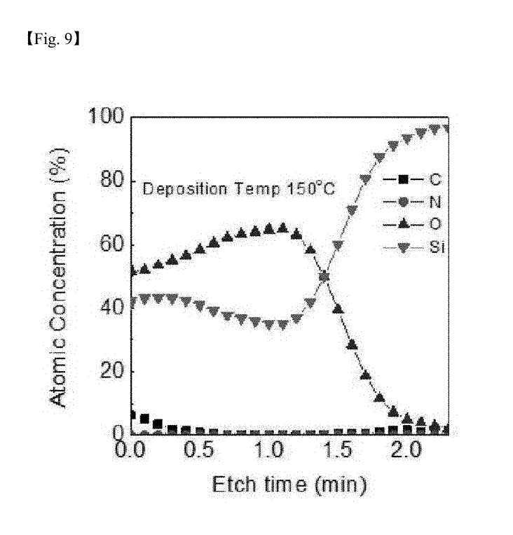

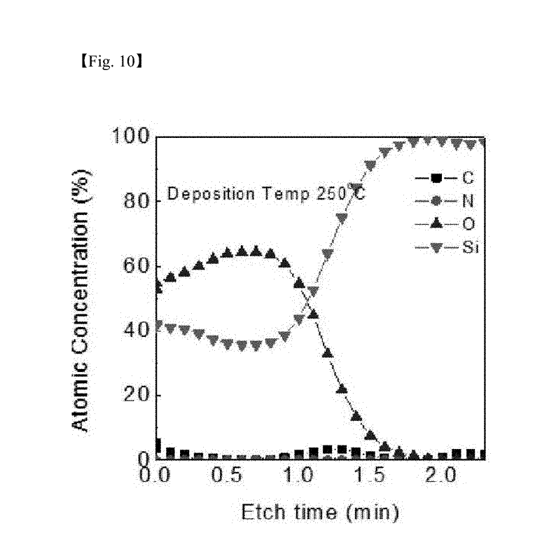

After injecting the aminosilane precursor, the result was purged with a purge gas (Ar 50 sccm, 8 s), and 150 g/cm³ to 200 g/cm³ of ozone (O₃ generator, Ozonetech) was injected as a reaction gas for 10 seconds to 30 seconds with a pressure of 0.1 MPa to 0.3 MPa, and the result was purged with a purge gas (Ar 50 sccm, 8 s) to deposit SiO₂. Properties were evaluated for the SiO₂ thin layers prepared at each temperature, and the results are shown in FIG. 1 to FIG. 10.

### Comparative Examples 1 to 3

Silicon oxide (SiO₂) was deposited according to the ALD process described in Example 1 except that tris(dimethylamino)silane (TDMAS) was used in Comparative Example 1, hexachlorodisilane (HCDS) was used in Comparative Example 2, and bisdiethylaminosilane (BDEAS) was used in Comparative Example 3 as the aminosilane precursor.

Property Evaluation

For the SiO₂ thin layer deposited according to Example 1, a thickness was measured using a spectroscopic ellipsometer (MG-1000, NanoView), and TiN was deposited to 100 nm on the SiO₂/Si structure using a DC Magnetron sputter and a shadow mask and measured in order to measure electrical properties.

In order to identify impurities in the 20 nm SiO₂ thin layer, AES was measured, and X-ray photoelectron spectroscopy (XPS) was measured for the 5 nm SiO₂ deposited thin layer.

In order to measure electrical properties of the SiO₂ thin layer, capacitance-voltage (Agilent E4980A) and leakage current (HP 4156A) were measured for the 3.5 nm, 5.5 nm and 7.5 nm deposited thin layers.

FIG. 1 and FIG. 2 are graphs showing a silicon-containing thin layer growth per cycle depending on a precursor and an ozone injection time with a substrate temperature of 150° C., a precursor temperature of 60° C., a line temperature of 80° C. and an ozone concentration of 180 g/cm³. It was identified that the silicon precursor according to the present invention reacted with ozone, and the SiO₂ growth per cycle was saturated by a self-limiting reaction.

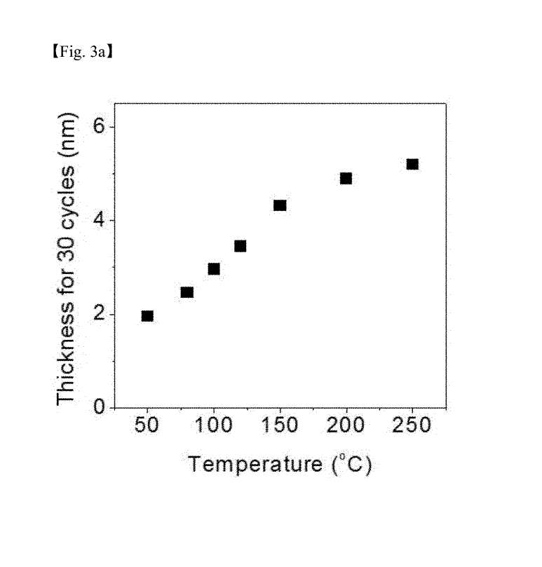

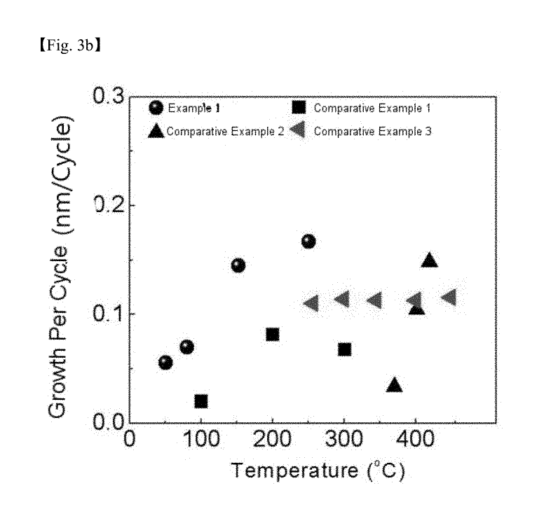

FIG. 3a is a graph showing a test result of cycle deposition in the same manner while varying the substrate temperature to 50° C. to 250° C. with a precursor injection time of 3 seconds and an ozone injection time of 20 seconds under the process condition of FIG. 1 and FIG. 2.

FIG. 3b is a graph showing the thin layer growth per cycle in the processes according to Example 1 and Comparative Examples 1 to 3. In Example 1, the deposition rate was favorable even at low temperatures, however, Comparative Example 1 had a very low thin layer growth per cycle compared to Example 1, and in Comparative Examples 2 and 3, it was identified that deposition only occurred at temperatures of 350° C. or higher and 250° C. or higher, respectively. Particularly, Comparative Example 2 had a very low thin layer growth per cycle even at a temperature of 350° C. or higher.

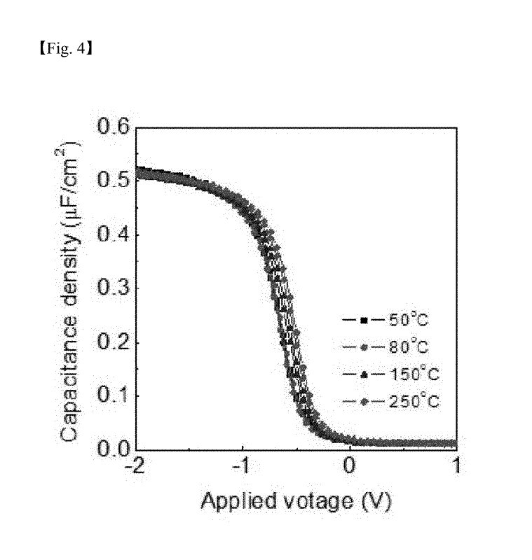

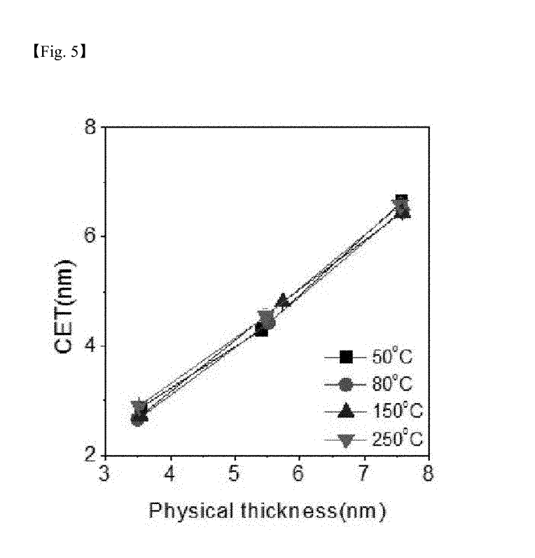

FIG. 4, FIG. 5 and FIG. 6 are graphs showing capacitance density, capacitance equivalent thickness (CET) and leakage current density, respectively, for the SiO₂ thin layer formed according to one example of the present invention. Properties of capacitance density, capacitance equivalent thickness (CET) and leakage current density were favorable at all temperatures when following the process according to the present invention.

As shown in FIG. 4 and FIG. 5, it was seen that excellent electrical properties were exhibited even for the SiO₂ thin layer deposited at low temperatures according to the present invention, and it was identified that, when deposition was carried out at the substrate temperature of 50° C., a k-value similar to when deposition was carried out at high temperatures was obtained.

However, as shown in FIG. 6, it was identified that leakage current decreased as the deposition temperature increased, and leakage current decreased as the SiO₂ thin layer film formed at high deposition temperatures became harder.

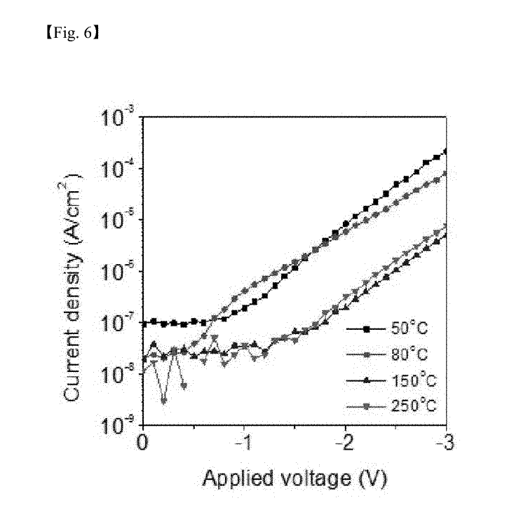

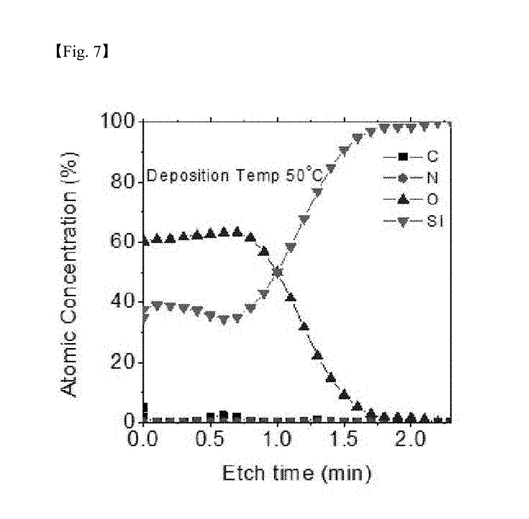

FIG. 7 to FIG. 10 are graphs showing results of measuring AES for identifying impurities for the SiO₂ thin layer deposited at each depositing temperature according to one example of the present invention, and as a result, the Si:O ratio was approximately 1:1.8, and C and N were present at a negligible level as an impurity level even in a low-temperature deposition process according to the present invention, and it was seen that purity of the formed thin layer was also very excellent.

### Example 2: Method for Forming Silicon-Containing Thin Layer Using PEALD

A substrate was prepared by, as a Si (100) wafer (LG Siltron inc) and p-type wafer having resistance of approximately 10 Ωcm, removing a native oxide layer after etching with a HF (10%) solution and washing with distilled water. On the Si wafer, silicon oxide (SiO₂) was deposited according to the following process using a 6-inch shower head type ALD reactor (CN-1 Co.).

The substrate was heated to a temperature of 50° C. to 200° C., and to the heated substrate, an aminosilane precursor heated to 60° C. was injected for 1 second to 15 seconds while maintaining a line temperature at 100° C. Herein, a precursor according to [Chemical Formula 5] was used as the silicon precursor.

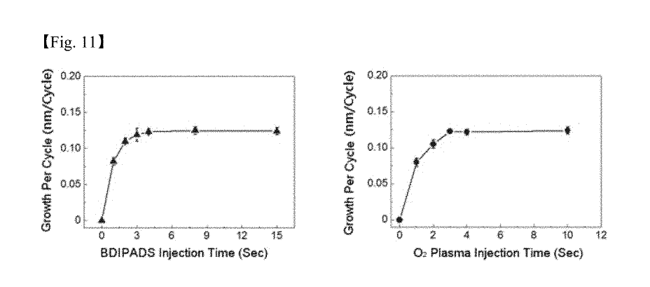

After injecting the aminosilane precursor, the result was purged with a purge gas (Ar 50 sccm, 8 s), and 200 sccm O₂ was prepared into a plasma state with electric power of 200 W. The O₂ in a plasma state, which is a reaction gas, was injected for 1 second to 10 seconds, and the result was purged with a purge gas (Ar 50 sccm, 8 s) to deposit SiO₂. Properties were evaluated for the SiO₂ thin layers prepared at each temperature, and the results are shown in FIG. 11 to FIG. 14.

### Comparative Example 4

Silicon oxide (SiO₂) was deposited according to the PEALD process described in Example 2 except that bisdiethylaminosilane (BDEAS, (Et₂N)₂SiH₂) was used as the aminosilane precursor in Comparative Example 4.

Property Evaluation

For the SiO₂ thin layer deposited according to Example 2, a thickness was measured using a spectroscopic ellipsometer (MG-1000, NanoView). XPS was measured for the 5 nm SiO₂ deposited thin layer to identify a Si:O ratio and an impurity concentration in the thin layer, and X-ray reflectivity (XRR) was measured to identify density of the thin layer.

FIG. 11 shows graphs of a SiO₂ thin layer growth per cycle depending on a precursor of Chemical Formula 5 and an O₂ plasma injection time by producing O₂ plasma under a condition of a substrate temperature of 150° C., a precursor temperature of 60° C., a line temperature of 100° C., and plasma electric power of 200 W. It was identified that atomic thin layer growth occurred by a self-limiting reaction and the SiO₂ growth per cycle was saturated. It was seen that a very excellent deposition rate was obtained when using the process according to the present invention.

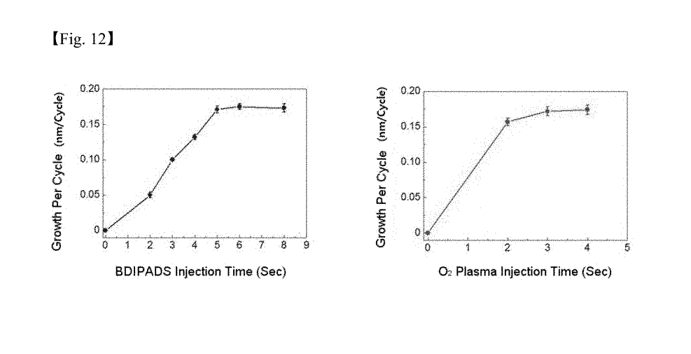

FIG. 12 shows graphs of a SiO₂ thin layer growth per cycle depending on a precursor of Chemical Formula 5 and an O₂ plasma injection time by producing O₂ plasma under a condition of a substrate temperature of 50° C., a precursor temperature of 60° C., a line temperature of 100° C., and plasma electric power of 200 W. It was seen that a very excellent deposition rate was obtained when using the process according to the present invention.

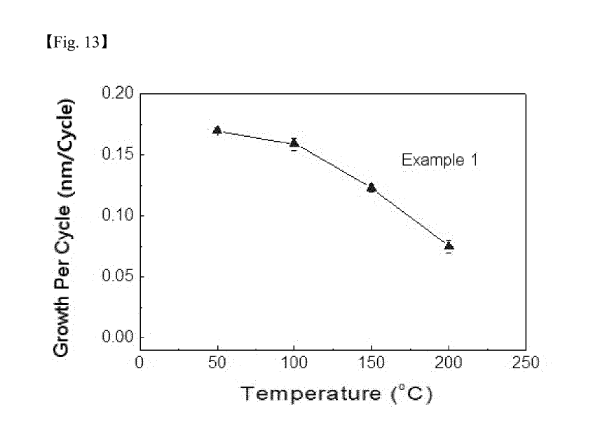

FIG. 13 shows a growth per cycle (GPC) of the silicon-containing thin layer prepared according to Example 2. It was identified that a favorable thin layer growth per cycle was obtained at temperatures of 200° C. or lower.

When measuring the SiO₂ thin layer prepared using the method of Example 2 with XPS, the Si:O ratio was approximately 1:1.7 to 1.8, and C and N were present at a negligible level as an impurity level even in a low-temperature deposition process according to the present invention, and it was seen that purity of the formed thin layer was also very excellent.

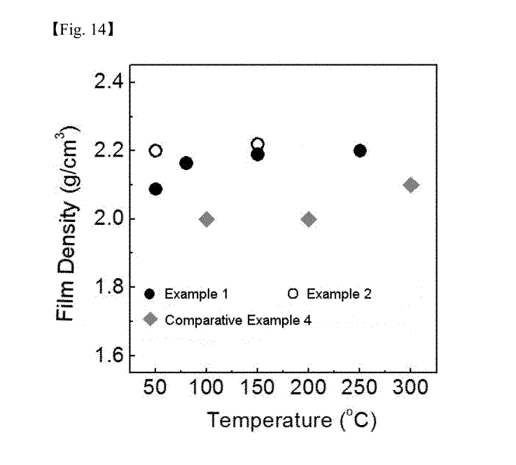

FIG. 14 is a graph showing a result of measuring X-ray reflectivity (XRR) for identifying physical density of the silicon-containing thin layer deposited at each deposition temperature according to the processes of Example 1, Example 2 and Comparative Example 4. Example 2 had density of 2.09 g/cm³ to 2.22 g/cm³ in a temperature section of 250° C. or lower, and exhibited excellent density at low temperatures compared to Comparative Example 4. In addition, it was identified that high silicon-containing thin layer density was obtained even at low temperatures, which is similar to Example 1 using O₃ as a reaction gas.

The method for forming a silicon-containing thin layer according to the present invention is carried out as a low temperature process that does not require a separate catalyst, and has excellent thin layer deposition rate and process efficiency.

In addition, the silicon-containing thin layer formed according to the present invention has excellent electrical properties such as a dielectric constant, and is useful in forming various devices structure bodies including a semiconductor device.

1. A method for forming a silicon-containing thin layer through atomic layer deposition (ALD) at a temperature of 250° C. or lower, wherein an aminosilane precursor represented by the following Chemical Formula 3, 4, 5, or 6 is used:

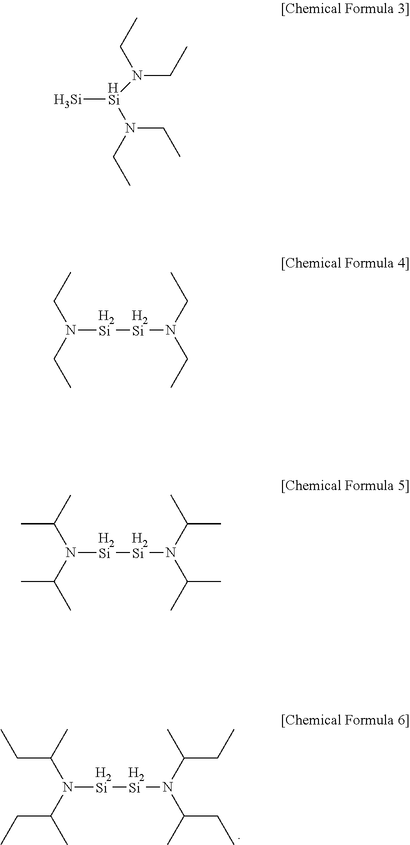

2. The method of claim 1, comprising:
a. increasing a temperature of a substrate to 20° C. to 250° C. by providing the substrate to an atomic layer deposition reactor;
b. introducing one or more of the aminosilane precursors into the reactor; and
c. introducing a reaction gas into the reactor.

3. (canceled)

4. (canceled)

5. The method of claim 1, wherein the silicon-containing thin layer is a thin layer including silicon oxide (SiOₓ), silicon nitride (SiNₓ), silicon oxynitride (SiOₓN_{y}), silicon carbide (SiCₓ), silicon carbonitride (SiCₓN_{y}) or combinations thereof.

6. The method of claim 2, wherein the reaction gas is an oxygen source gas, a nitrogen source gas, a carbon source gas or a combination thereof.

7. The method of claim 6, wherein the reaction gas is H₂O, O₂, O₃, N₂, NH₃, N₂H₄, NO, N₂O, NO₂, CO, CO₂ or a combination thereof.

8. (canceled)

9. (canceled)

10. (canceled)

11. The method of claim 1, wherein the aminosilane precursor is represented by the following Chemical Formula 5:

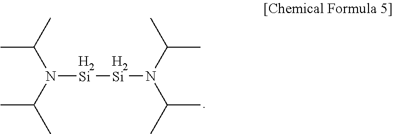

12. A silicon-containing thin layer prepared by the method for forming a silicon-containing thin layer of claim 1.

13. The method of claim 5, wherein the reaction gas is an oxygen source gas, a nitrogen source gas, a carbon source gas or a combination thereof.

14. A silicon-containing thin layer prepared by the method for forming a silicon-containing thin layer of claim 2.

15. A silicon-containing thin layer prepared by the method for forming a silicon-containing thin layer of claim 5.

16. A silicon-containing thin layer prepared by the method for forming a silicon-containing thin layer of claim 6.

17. A silicon-containing thin layer prepared by the method for forming a silicon-containing thin layer of claim 7.
